(19) United States
(12) Patent Application Publication
(10) Pub. No.: US 2024/0322283 A1
(43) Pub. Date: Sep. 26, 2024

(54) BATTERY CELL HEATING SYSTEM

(71) Applicant: ZHUHAI COSMX POWER CO., LTD., Zhuhai (CN)

(72) Inventors: Zhenjiang ZHAN, Zhuhai (CN); Zihao LUO, Zhuhai (CN); Lujia YU, Zhuhai (CN); Yali SUN, Zhuhai (CN); Fangjun LIAO, Zhuhai (CN); Xiaoming WANG, Zhuhai (CN)

(21) Appl. No.: 18/736,182

(22) Filed: Jun. 6, 2024

Related U.S. Application Data
(63) Continuation of application No. PCT/CN2023/086024, filed on Apr. 3, 2023.

(30) Foreign Application Priority Data
Jun. 30, 2022 (CN) 202221680358.X
Jun. 30, 2022 (CN) 202221680359.4
Jun. 30, 2022 (CN) 202221690815.3

(51) Int. Cl. H01M 10/615; H01M 10/42; H01M 10/44; H01M 10/48; H01M 10/63; H01M 10/6572; H10N 10/13

(52) U.S. Cl. CPC H01M 10/615; H01M 10/425; H01M 10/443; H01M 10/486; H01M 10/63; H01M 10/6572; H10N 10/13

(57) ABSTRACT

The present application discloses a battery cell heating system, includes: cells, a heating element, an energy storage module, a heat source, a cold source, and a thermoelectric conversion module; where the heating member is in contact with the cells; the energy storage module is electrically connected to the heating member to supply electric energy to the heating member to generate heat energy; and the thermoelectric conversion module is in contact with the heat source and the cold source respectively, and the thermoelectric conversion module is electrically connected to the energy storage module, so as to store generated electric energy to the energy storage module.

### CROSS-REFERENCE TO RELATED APPLICATIONS

The present application a continuation of International Application No. PCT/CN2023/086024, filed on Apr. 3, 2023, which claims priority to the Chinese application patent with Patent Application No. 20/222,1680358.X filed on Jun. 30, 2022 and entitled with “BATTERY MODULE”, the Chinese application patent with Patent Application No. 20/222,1680359.4 filed on Jun. 30, 2022 and entitled with “BATTERY MODULE”, and the Chinese application patent with Patent Application No. 20/222,1690815.3 filed on Jun. 30, 2022 and entitled with “BATTERY AND ELECTRONIC DEVICE”, all of which are hereby incorporated by reference in their entireties.

### TECHNICAL FIELD

The present application relates to the technical field of batteries and, in particular, to a battery cell heating system.

### BACKGROUND

With the continuous progress of science and technology, more and more electronic products have entered people's daily lives. Many electronic products are developing towards a wireless direction, and energy of wireless electronic products comes from batteries of the products. With the improvement in performance requirements of products, the performance requirements for batteries of the products are also higher and higher.

At present, the most severe heat generation position in most of the electronic products is generally a battery cell or a chip on a circuit board. Conventional designs for these positions with high heat generation are aimed to dissipate heat by enhancing convection with the outside in a manner such as adding fins, providing windows in a housing, and using high thermal conductivity materials to conduct heat to the housing. The final heat is dissipated to the outside world and a part of energy is lost for batteries, causing a problem of heat waste of batteries. In some cold regions, the demand for wireless electronic devices is also increasing gradually. However, under cold conditions, the discharge performance of batteries is severely limited, and even cause electronic devices to fail to work normally, so that batteries needs to be heated so as to ensure the normal operation of electronic products.

In the prior art, an external heating device is generally provided for heating a battery, or a heating device is added inside a battery for heating by power supply. However, this needs for an assurance of good heat or power supply conditions in the outside world, but in some extremely cold regions, such as the outside of scientific research stations for expedition, it is not possible to ensure the heating conditions for batteries. Furthermore, such heating manner may cause a problem of excessively high costs for battery heating.

### SUMMARY

The present application provides a battery cell heating system, which solves the problems of heat waste of batteries and excessive high heating costs under cold conditions.

The present application provides a battery cell heating system, including: a cell set, a heating member, an energy storage module, a heat source, a cold source, and a thermoelectric conversion module, where the heating member is in contact with the cell set; the energy storage module is electrically connected to the heating member so as to supply electric energy to the heating member to generate heat energy; and the thermoelectric conversion module is in contact with the heat source and the cold source respectively, and thermoelectric conversion module is electrically connected to the energy storage module so as to store generated electric energy to the energy storage module.

In some embodiments, the cold source is a heat dissipating sheet, and the battery cell heating system further includes a heat conducting sheet, and the heat conducting sheet is in contact with the heat source, and the thermoelectric conversion module is in contact with the heat conducting sheet and the heat dissipating sheet respectively.

In an implementation, the cell set includes a plurality of cells arranged in parallel; and the heating member includes a plurality of heating portions arranged in parallel in an arrangement direction of the cells, and first connecting portions, each of which connects two adjacent heating portions; and at least one surface of each of the cells is in contact with each of the heating portions, respectively.

In an implementation, each of the cells includes two first side surfaces provided opposite to each other and two second side surfaces provided opposite to each other; the first side surfaces have an area greater than that of the second side surfaces; and at least one of the first side surfaces of each of the cells is in contact with each of the heating portions, respectively.

In some possible embodiments, the heat source is the cells, the heating member is a heating sheet, and the heat dissipating sheet is located on one side of the heat conducting sheet away from the cells; and the cells are in contact with the heating sheet and the heat conducting sheet, respectively.

In an implementation, each of the first connecting portions is provided with a slot, the heat conducting sheet includes heat conducting portions, each of which is inserted to the slot, and the heat conducting sheet and the heating sheet form a folding structure; and at least one cell is located between each of the heat conducting portions and each of the heating portions.

In an implementation, the heat conducting sheet includes second connecting portions, each of which connects adjacent heat conducting portions, and the second connecting portions are in contact with the thermoelectric conversion module.

In an implementation, in the arrangement direction of the cells, the folding structure includes the heat conducting portions, two of which are located on two opposite sides of the folding structure, respectively.

In an implementation, a length of each of the heating portions is greater than a length of each of the heat conducting portions, and/or, in a height direction of the battery cell heating system, a height of the thermoelectric conversion module is higher than that of the heat conducting sheet; and/or each of the cells includes a shell and a cell body, where the shell includes an encapsulation portion for encapsulating the cell body and a sealing edge located at one side of the encapsulation portion, and the sealing edge is bent towards to a direction close to the cell body, and/or each of the cells includes a shell and a cell body, where the shell includes an encapsulation portion for encapsulating the cell body, and adjacent cells have encapsulation portions disposed opposite to each other, and/or the battery cell heating system further includes buffer members located between the cells and the heating portions respectively, and/or, located between the cells and the heat conducting portions, respectively.

In an implementation, each of the cells includes a first cell located at a first side and a second cell located at a second side opposite to the first side; and two first side surfaces of the first cell are in contact with each heat conducting portion and each heating portion respectively, and/or the two second side surfaces of the second cell are in contact with each first connecting portion and the second connecting portion respectively.

In an implementation, an angle is formed between each heat conducting portion and each second connecting portion, and the angle is an arc angle or a linear angle.

In other possible embodiments, the heat source is a heating element, and the heating element is a heating film, the battery cell heating system further includes a housing, a groove matching the heat dissipating sheet is provided on the housing, and the heat dissipating sheet is provided in the groove; and the thermoelectric conversion module is electrically connected to the heating sheet, and the heating sheet heats the cells through the thermoelectric conversion module.

In an implementation, the heat dissipating sheet is a finned, the heat dissipating sheet is evenly provided on one surface of the thermoelectric conversion module, and the other surface of the thermoelectric conversion module is connected to the heating element.

In an implementation, the battery cell heating system further includes a circuit board, where one end of the circuit board is in contact with the thermoelectric conversion module, and the heating element is connected to the other end of the circuit board.

In an implementation, each of the cells includes a first cell located at a first side and a second cell located at a second side opposite to the first side; and two first side surfaces of the first cell are in contact with the heat conducting portions respectively, and/or two first side surfaces of the second cell are in contact with the heat conducting portions respectively.

In an implementation, an angle is formed between each of the heating portions and each of the first connecting portions, and the angle is an arc angle or a linear angle.

In an implementation, the angle is in a range of 0-90°.

In an implementation, at least two cells are accommodated between two adjacent heating portions.

In some other possible embodiments, the cell set includes a first cell unit and a second cell unit; and the heating member includes a connecting area and a heat conducting area, where the connecting area is configured to be connected with an energy storage module, the heat conducting area is attached to the second cell unit, and the heating member is configured to conduct heat energy to the heat conducting area through the connecting area when a temperature difference between the first cell unit and the second cell unit is greater than a preset value, and the heating member forms the heat conducting area.

In an implementation, the heating member further includes a measuring area, and the measuring area extends from the heat conducting area to the first cell unit, and the measuring area is attached to the first cell unit. The measuring area is provided with a first temperature sensor, the heat conducting area is further provided with a second temperature sensor, where the first temperature sensor is configured to measure the temperature of the first cell unit, and the second temperature sensor is configured to measure the temperature of the second cell unit.

In an implementation, the number of the cells in the first cell unit along a thickness direction of the first cell unit is larger than 1, and the measuring area is provided between any two adjacent cells in the first cell unit.

In an implementation, the heat conducting area is provided with a plurality of heat conducting structures, and the plurality of heat conducting structures are arranged at intervals.

In an implementation, the plurality of heat conducting structures are arranged parallel to each other in the heat conducting area.

In an implementation, distances between the plurality of heat conducting structures are greater than or equal to 5 mm, and/or the plurality of heat conducting structures have a thickness of greater than or equal to 0.05 mm, and the plurality of heat conducting structures have a thickness of less than or equal to 0.2 mm.

In an implementation, the heating member includes a first insulation layer, a second insulation layer, where the first insulation layer and the second insulation layer are located on opposite sides of the heating member respectively, where the heating element is located in the heat conducting area, and the heating member further includes a connector located in the connecting area, and the heating member is electrically connected to the connector through a control circuit.

In an implementation, the battery cell heating system further includes a control module, where the control module is connected to the energy storage module, and the control module is configured to control the thermoelectric conversion module to charge the energy storage module or control the heating sheet to heat the cells.

In an implementation, the battery cell heating system further includes an amplifying module, where the amplifying module is provided between the thermoelectric conversion module and the energy storage module, and is respectively connected to the thermoelectric conversion module and the energy storage module, and the amplifying module is configured to amplify a voltage generated by the thermoelectric conversion module and transmit it to the energy storage module so as to charge the energy storage module.

In an implementation, the thermoelectric conversion module is connected to a first end of the energy storage module, and the connector of the heating member is connected to a second end of the energy storage module.

In an implementation, the thermoelectric conversion module includes a first connecting member and a second connecting member, where two ends of the first connecting member are respectively connected to the heat source and the cold source; and two ends of the second connecting member are respectively connected to the heat source and the cold source; and the end of the first connecting member and the end of the second connecting member, which are close to the cold source, are connected to the amplifying module and the control module.

In an implementation, the thermoelectric conversion module is respectively connected to the heat source and the cold source by a thermal conductive adhesive.

In an implementation, the end of the first connecting member and the end of the second connecting member, which are close to the cold source, are connected to a first end of the amplifying module, a second end of the amplifying module is connected to a first end of the control module, and a second end of the control module is connected to the energy storage module.

The present application provides a battery cell heating system, which can convert waste heat generated during operation of a heat source of the battery cell heating system into electric energy and store electric energy in an energy storage device and can also convert electric energy in the energy storage device into heat and provides heat to the cells when a battery is started under cold conditions, thereby avoiding the additional use of an external heating device, achieving the effect of saving the battery use cost, improving the battery use period, and improving the ability of battery use cycling.

It should be understood that what is described in this section is not intended to identify critical or important features of the embodiments of the present application, and is not intended to limit the scope of the present application. Other features of the present application will be easily understood through the following description.

### BRIEF DESCRIPTION OF THE DRAWINGS

In order to describe the technical solutions in the embodiments of the present application or in the prior art more clearly, a brief introduction will be given for describing the accompanying figures required in the embodiments or prior art. Obviously, the accompanying figures in the following description show some embodiments of the present application. For those skilled in the art, other accompanying figures can be obtained based on these figures without creative efforts. Among them:

FIG. 1 is a first schematic structural diagram of a battery module used as a battery cell heating system according to Embodiment 1 of the present application.

FIG. 2 is a second schematic structural diagram of the battery module used as the battery cell heating system according to the Embodiment 1 of the present application.

FIG. 3 is a third schematic structural diagram of the battery module used as the battery cell heating system according to the Embodiment 1 of the present application.

FIG. 4 is a schematic structural diagram of a heat conducting sheet according to the Embodiment 1 of the present application.

FIG. 5 is a schematic structural diagram of a heating sheet according to the Embodiment 1 of the present application.

FIG. 6 is a schematic structural diagram of a folding structure according to the Embodiment 1 of the present application.

FIG. 7 is a schematic block diagram of the battery cell heating system according to the Embodiment 1 of the present application.

FIG. 8 is a schematic diagram of a circuit structure of the battery cell heating system according to the Embodiment 1 of the present application.

FIG. 9 is a schematic diagram of an internal structure of the battery module used as a battery cell heating system according to Embodiment 2 of the present application.

FIG. 10 is a schematic explosive structural diagram of the battery module used as the battery cell heating system according to the Embodiment 2 of the present application.

FIG. 11 is a schematic structural diagram of a heating member according to the Embodiment 2 of the present application.

FIG. 12 is a schematic block diagram of the battery cell heating system according to the Embodiment 2 of the present application.

FIG. 13 is a schematic diagram of a circuit structure of the battery cell heating system according to the Embodiment 2 of the present application.

FIG. 14 is a first schematic structural diagram of a battery module of an electronic device used as a battery cell heating system according to Embodiment 3 of the present application.

FIG. 15 is an overall schematic diagram of the battery module according to the Embodiment 3 of the present application.

FIG. 16 is a second schematic structural diagram of the battery module according to the Embodiment 3 of the present application.

FIG. 17 is a schematic structural diagram of a thermoelectric conversion module 110 of the electronic device used as the battery cell heating system according to the Embodiment 3 of the present application.

### LIST OF REFERENCE NUMBERS

10—battery cell heating system;
100—heat source; 110—thermoelectric conversion module; 120—cold source; 130—amplifying module; 140—energy storage module; 150—control module; 160—heating module; 170—first thermoelectric material; 180—second thermoelectric material; 190—heat source connecting sheet; 200—cold source connecting sheet; 210—thermoelectric module;
1—cell set; 11—first cell unit; 12—second cell unit;
2—heating member; 21—heating portion; 22—first connecting portion; 23—groove; 24—connecting wire; 25—connecting area; 26—heat conducting area; 27—measuring area;
3—heat conducting sheet; 31—heat conducting portion; 32—second connecting portion;
4—housing; 41—upper housing; 42—lower housing;
5—heating element;
6—heat dissipating sheet;
7—foam.

### DESCRIPTION OF EMBODIMENTS

The technical solutions in the embodiments of the present application will be described clearly and completely in the following with reference to the accompanying figures in the embodiments of the present application. Obviously, the embodiments to be described are merely a part rather than all of the embodiments of the present application. In the absence of conflict, the following embodiments and features in the embodiments may be combined with each other. All other embodiments obtained by those ordinary skilled in the art based on the embodiments of the present application without creative efforts shall fall within the scope of protection of the present application.

Unless otherwise defined, technical terms or scientific terms used in the present application shall have a common meaning understood by those skilled in the art. The terms “first”, “second” and similar terms used herein do not indicate any order, quantity, or importance, but rather are used to distinguish different components. Similarly, the terms such as “a” or “an” do not indicate a quantity limitation, but rather indicate the presence of at least one. The terms such as “connected” or “connection” are not limited to physical or mechanical connections, but may include electrical connections, regardless of whether it is direct or indirect. The terms such as “up”, “down”, “left”, “right” and similar terms are only used to represent relative positional relationships, and when an absolute position of a described object changes, the relative positional relationship also changes accordingly.

The present application provides a battery cell heating system 10, including: a cell set 1, a heating member 2, an energy storage module 140, a heat source 100, a cold source 120 and a thermoelectric conversion module 110. Among them, the heating member 2 is in contact with cells 13 so as to heat the cells 13 in the cell set 1. The energy storage module 140 is electrically connected to the heating member 2 to supply electric power to the heating member 2 to generate heat energy. The thermoelectric conversion module 110 is in contact with the heat source 100 and the cold source 120 respectively, and the thermoelectric conversion module 110 is electrically connected to the energy storage module 140 so as to store generated electric energy to the energy storage module 140. In this way, the waste heat generated during operation of the heat source 100 of the battery cell heating system 10 can be converted into electric energy and then the electric energy can be stored in the energy storage module 140. When the battery is started, the electric energy in the energy storage module 140 can be converted into heat and the heat can be provided to the cells 13, thereby avoiding additional use of an external heating device, achieving the effects of saving the battery use costs and improving the battery use period, and improving the ability of battery use recycle.

### Embodiment 1

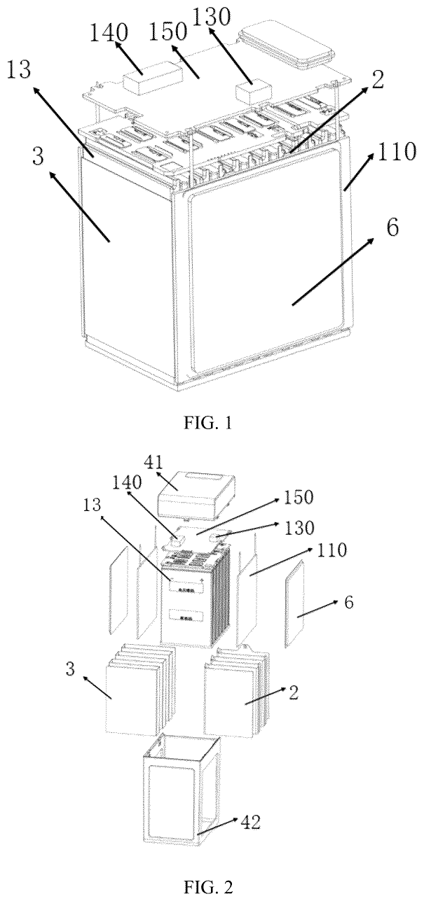

Referring to FIG. 1 to FIG. 3, the battery cell heating system 10 provided in the Embodiment 1 is a battery module. FIGS. 1, 2 and 3 are schematic structural diagrams of the battery module according to Embodiment 1. The battery module may include: a cell set 1, a heat dissipating sheet 6, a thermoelectric conversion module 110, a heat conducting sheet 3, and a heating sheet;
the heat dissipating sheet 6 is located at one side of the heat conducting sheet 3 away from cells 13;
the cells 13 are in contact with the heating sheet and the heat conducting sheet 3 respectively;
the thermoelectric conversion module 110 is in contact with the heat conducting sheet 3 and the heat dissipating sheet 6 respectively.

In this embodiment, the cells 13 themselves may serve as a heat source 100, and the heat dissipating sheet 6 may serve as a cold source 120. The heat conducting sheet 3 may be a high heat conducting thin sheet. The heating sheet may serve as a heating member 2 for heating the cells 13, and the heating sheet may be a heating thin sheet. The heat dissipating sheet 6 may be an exposed aluminum sheet. The thermoelectric conversion module is provided between a folding position of the high heat conducting thin sheet and the exposed aluminum sheet. In order to enable the exposed aluminum sheet to better receive heat from the cells 13, a heat conducting silicone grease can also be added between the exposed aluminum sheet and side edges of the cells 13 to enhance the heat conducting effect. The cells 13 are provided between the high heat conducting thin sheet and the heating thin sheet, and the temperature of the cells 13 can be maintained or cells 13 can be heated according to the temperature provided by the high heat conducting thin sheet and the heating thin sheet. The thermoelectric conversion module 110 is configured to convert heat between the heat source 100 and the cold source 120 into electric energy and stores the electric energy in a battery, a capacitor, and other electric storage device. After the adjustment and control of a control circuit, electric energy can be provided to the heating thin sheet and the high heat conducting thin sheet inside the battery under cold conditions to provide heat for the cells 13, so that the battery can reach a good discharge temperature under cold conditions without an external power supply, thereby ensuring the normal discharge capacity of the battery and providing a stable power for the operation of the device. If the thermoelectric conversion module 110 is provided on a front side of the cells 13, only the heat from the outermost cell 13 can be well absorbed, the heat from the inner cells 13 is difficult to be absorbed, and will occupy the thickness space of the cells 13. In addition to the high heat conducting thin sheet and the heating thin sheet, a certain amount of foam 7 needs to be added between the cells 13, so as to absorb the thickness expansion of the cells 13 after cycling thereof. A control module 150 is provided with an energy storage module 140 and an amplifying module 130. The battery further includes a battery upper housing 41 and a battery lower housing 42, where the battery upper housing 41 is provided on the control module 150, and the battery lower housing 42 is provided outside the folding structure. The thermoelectric conversion module 110 and the exposed aluminum sheet are provided outside the folding structure in sequence.

The present application provides a battery module, including: the cell set 1, the heat dissipating sheet 6, the thermoelectric conversion module 110, the heat conducting sheet 3 and a heating sheet. The heat dissipating sheet 6 is located at one side of the heat conducting sheet 3 away from the cells 13. Each of the cells 13 is in contact with the heating sheet and the heat conducting sheet 3 respectively. The thermoelectric conversion module 110 is in contact with the heat conducting sheet 3 and the heat dissipating sheet 6, respectively. The embodiments of the present application provide a battery module which can convert waste heat of the cells 13 into electric energy and stores electric energy in an energy storage device, and can also convert the electric energy in the energy storage device into heat and provides heat to the cells 13 when the battery is started under cold conditions, thereby avoiding the additional use of an external heating device and achieving the effect of saving battery use costs.

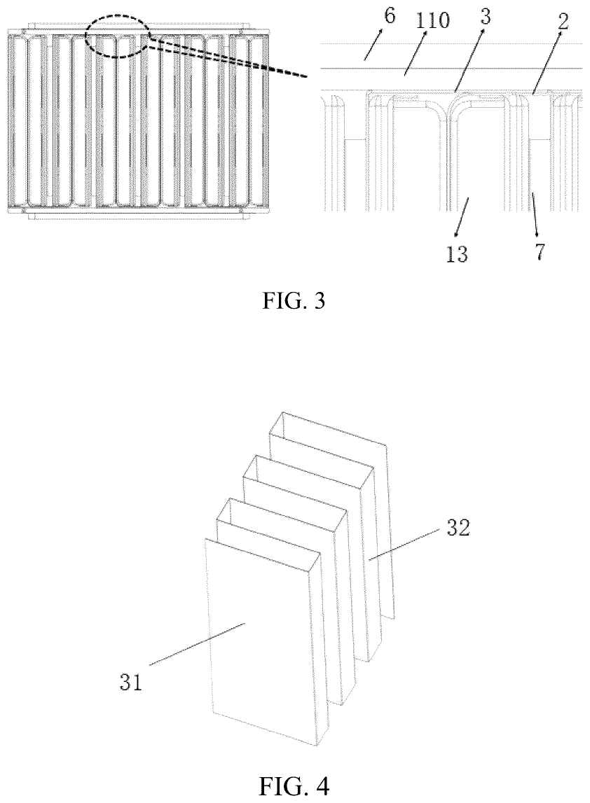

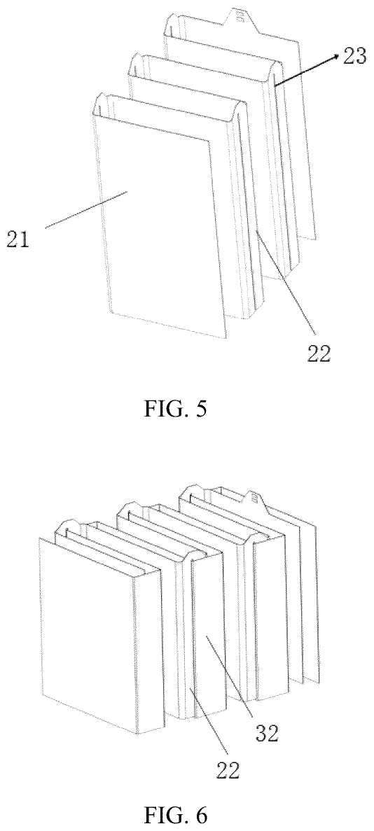

In another embodiment, referring to FIG. 3 to FIG. 5, FIG. 3 is a schematic structural diagram of the heat conducting sheet 3 according to this embodiment, FIG. 4 is a schematic structural diagram of the heating sheet according to this embodiment, and FIG. 5 is a schematic structural diagram of the folding structure according to this embodiment.

In an implementation, the cell set 1 includes a plurality of cells 13 arranged in parallel;
the heating sheet includes a plurality of heating portions 21 arranged in parallel along the arrangement direction of the cells 13; first connecting portions 22, each of which connects two adjacent heating portions 21; and slots 23 provided in the first connection portions 22 respectively;
the heat conducting sheet 3 includes heat conducting portions 31 inserted in the slots 23, and the heat conducting sheet 3 and the heating sheet form the folding structure; and
at least one cell 13 is located between each of the heat conducting portions 31 and each of the heating portions 21.

In this embodiment, the heating sheet is the heating thin sheet, the heat conducting sheet 3 is the high heat conducting thin sheet, where the heating thin sheet includes a plurality of heating portions 21 and first connecting portions 22, and further includes the slots 23 in the first connecting portions 22. The high heat conducting thin sheet matches the heating thin sheet through the slots 23 to form the folding structure. In an implementation, at least two cells 13 are accommodated between adjacent heat conducting portions 31 or heating portions 21. According to the structure formed by the heat conducting portions 31 or the heating portions 21, one or more cells 13 are provided within the folding structure.

In an implementation, the heat conducting sheet 3 includes second connecting portions 32, each of which connects adjacent heat conducting portions 31, and the second connecting portions 32 are in contact with the thermoelectric conversion module 110.

In an implementation, in the arrangement direction of the cells 13, the folding structure includes heat conducting portions 31 located on two opposite sides of the folding structure respectively. The length of the heating portions 21 is shorter than that of the heat conducting portions 31; and/or in the height direction of the battery module, the height of the thermoelectric conversion module 110 is greater than that of the heat conducting sheet3; and/or each cell 13 includes a shell and an cell 13 body, where the shell includes an encapsulation portion for encapsulating the cell 13 body and a sealing edge located at one side of the encapsulation portion, the sealing edge is bent towards to a direction close to the cell 13 body; and/or each cell 13 includes a shell and a cell 13 body, where the housing includes an encapsulation portion for encapsulating the cell 13 body, and encapsulation portions of adjacent cells 13 are arranged opposite to each other; and/or the battery module further includes buffer members located between the cells 13 and the heating portions 21, and/or located between the cells 13 and the heat conducting portions 31, respectively.

In this embodiment, the high heat conducting thin sheet and the heating thin sheet both form folding structures, respectively, which together form a composite folding structure. Each of the cells 13 is placed between adjacent folding surfaces of the composite folding structure, and folding positions of the heating sheet are avoided from the positions of the slots 23 for the assembly with the high heat conducting thin sheet. The folding positions need to ensure that the high heat conducting thin sheet is located in the outer side and the heating sheet is located in the inner side, so as to ensure that the high heat conducting thin sheet is in better contact with the thermoelectric conversion module 110 located outside. The composite folding structure may cause at least one large surface of each cell 13 to be in contact with the heating thin sheet, so that respective cells 13 are heated more evenly. Moreover, due to the high thermal conductivity of the high heat conducting thin sheet, temperature differences between respective cells 13 are further balanced, so that the temperatures of respective cells 13 are close to the same temperature during the operation of the battery module, thereby improving the service life of the battery. Furthermore, the heating thin sheet may also be connected to the control module 150 through a wire, so that the control module 150 can control working conditions of the heating thin sheet.

In an implementation, each of the cells 13 includes two first side surfaces disposed opposite to each other and two second side surfaces disposed opposite to each other;
the first side surfaces have an area greater than that of the second side surfaces; and
at least one of the first side surfaces of each of the cells 13 is in contact with the heating portion 21.

In an implementation, each cell 13 includes a first cell 13 located at a first side and a second cell 13 located at a second side opposite to the first side;
two first side surfaces of the first cell 13 are in contact with the heat conducting portion 31 and the heating portion 21 respectively, and/or
two second side surfaces of the second cell 13 are in contact with the first connecting portion 22 and the second connecting portion 32 respectively.

In an implementation, an angle is formed between the heat conducting portion 31 and the second connecting portion 32 and/or between the heating portion 21 and the first connecting portion 22, and the angle is an arc angle or a linear angle.

In this embodiment, the cell 13 is in a long body shape, and is provided between adjacent heat conducting portions 31. The first side surface of the cell 13 is a surface having a larger area, and the second side surface is a surface having a smaller area. By contacting the surface having the larger area with the heat conducting portion 31, the cell 13 can be better heated. Two or more cells 13 are accommodated between adjacent heat conducting portions 31, and the specific number of the cells can be is adjusted according to actual situations. The angle between the heat conducting portion 31 and the second connecting portion 32 generally needs to be less than 90°, and when the angle is greater than 90°, the cell 13 cannot completely contact the heat conducting portion 31, thereby causing a problem of uneven heating.

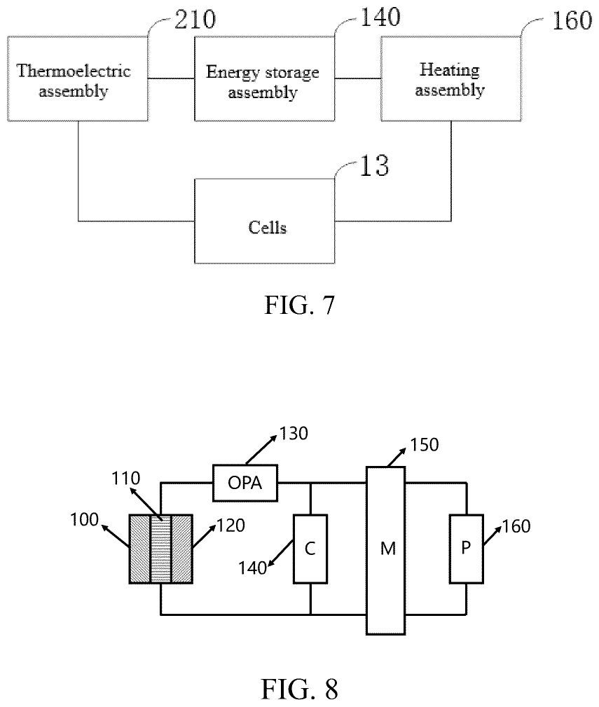

Referring to FIG. 7, FIG. 7 is a schematic module diagram of the battery module used as the battery cell heating system 10 according to the embodiments of the present application. Specifically, the battery module includes: a thermoelectric module 210, the cells 13, an energy storage module 140, and a heating module 160;
the thermoelectric module 210 is electrically connected to the energy storage module 140, the energy storage module 140 is electrically connected to the heating module 160, and the heating module 160 and the thermoelectric module 210 are in contact with the cells 13;
the thermoelectric module 210 is configured to generate a first voltage according to a temperature difference between a cold end of the thermoelectric module 210 and a surface of the cells 13;
the energy storage module 140 is configured to charge according to the first voltage, and when a preset condition is satisfied, the energy storage module 140 releases a second voltage generated according to the first voltage; and
the heating module 160 is configured to convert the second voltage to a first heat and provide the cells 13 with the first heat.

In this embodiment, the thermoelectric module 210 utilizes the Seebeck effect thermoelectric conversion technology and provides the thermoelectric conversion module 110 on the side edges of the cells 13. The thermoelectric conversion module 110 includes multiple groups of thermoelectric conversion units. The thermoelectric conversion units can convert heat generated during the operation of battery into electric energy, which is subjected to voltage amplification and charging and discharging control process by a control circuit, then can be stored in a battery, a capacitor and other storage devices, thereby effectively solving the heating problem of the battery, reducing the temperature of critical components such as the cells 13, improving the working performance and service life of the battery, and enhancing the user experience.

Specifically, in an implementation, the thermoelectric module 210 includes a heat source 100, a thermoelectric conversion module 110 and a cold source 120. The thermoelectric conversion module 110 is provided between the heat source 100 and the cold source 120, and the thermoelectric conversion module 110 is in contact with the heat source 100 and the cold source 120 respectively. The cold source 120 is an aluminum sheet and the heat source 100 is the cells 13, the heat from the heat source 100 is conducted through the high heat conducting thin sheet, then is absorbed and converted into electric energy by the thermoelectric conversion module. The thermoelectric conversion module 110 is contacted with the aluminum sheet, both of which are sequentially disposed on the surface of the high heat conducting thin sheet.

Among them, the waste heat generated during the operation of the cell 13 is used as the heat source 100, and a layer of an exposed aluminum sheet located on the housing 4 is used as the cold source 120, so that heating can be performed in the presence of a temperature difference, and the heating effect is better when the battery is in cold conditions. The first voltage is generated by the temperature difference between the heat source 100 and the cold source 120 as well as the thermoelectric conversion module 110. It should be noted that the first voltage is generally lower than a charging voltage of the energy storage module 140, and the first voltage needs to be amplified by the amplifying module 130, then it can be higher than the charging voltage of the energy storage module 140.

In another embodiment, referring to FIG. 8, FIG. 8 is a schematic structural diagram of a circuit in this embodiment. The thermoelectric conversion module 110 is provided between the heat source 100 and the cold source 120, and the heat source 100, the cold source 120 and the thermoelectric conversion module 110 are combined to form the thermoelectric module 210. In an implementation, the amplifying module 130 is further included, and the amplifying module 130 is provided between the thermoelectric module 210 and the energy storage module 140, and is electrically connected to the thermoelectric module 210 and the energy storage module 140 respectively. The amplifying module 130 is configured to amplify the first voltage to charge the energy storage module 140. In an implementation, a control module 150 is further included, and the control module 150 is electrically connected to the energy storage module 140, and the control module 150 is configured to control the charging and discharging processes of the energy storage module 140. In an implementation, the control module 150 is a circuit board, and both the amplifying module 130 and the energy storage module 140 are provided on the circuit board.

Among them, the thermoelectric conversion module 110 is provided between the heat source 100 and the cold source 120, where the thermoelectric conversion module 110 includes multiple groups of thermoelectric conversion units which are configured to generate the first voltage. The thermoelectric conversion module 110, the amplifying module 130 and the energy storage module 140 form a loop. The energy storage module 140, the control module 150 and the heating thin sheet in the heating module 160 form a loop. Specifically, the amplifying module 130 can use electronic components having circuit amplification function to amplify the potential difference generated by the thermoelectric conversion module 110. A voltage value of electrical energy is stored in the energy storage module 140. For example, an operational amplifier is used as an example in this embodiment, other circuit amplification devices can also be selected. Various devices with energy storage capabilities can be selected as the energy storage module 140, such as capacitors, or batteries specially designed for being used at low temperature, etc., and can be adaptively selected according to actual situations, without specific limitations in this embodiment. The control module 150 can control the charging and discharging process of the energy storage module 140, and can cause the electric energy stored in the energy storage module 140 to be released, adjusted, and matched, and then supplied to the heating thin sheet when the cells 13 need to be heated, and the control module 150 has circuit protection function at the same time.

The battery cell heating system 10 provided in Embodiment 1 of the present application is a battery module. The battery module includes: a cell set 1, a heat dissipating sheet 6, a thermoelectric conversion module 110, a heat conducting sheet 3, and a heating sheet. The heat dissipating sheet 6 is located on one side of the heat conducting sheet 3 away from cells 13. The cells 13 are in contact with the heating sheet and the heat conducting sheet 3 respectively. The thermoelectric conversion module 110 is in contact with the heat conducting sheet 3 and the heat dissipating sheet 6 respectively. The battery module provided in the embodiments of the application serves as the battery cell heating system 10, which can convert waste heat of the cells 13 into electrical energy and store it in the energy storage device, and then can convert electrical energy in the energy storage device into heat and provide the heat to the cells 13 when the battery is started under cold conditions, thereby avoiding additional use of an external heating device and achieving the effect of saving the battery use costs.

### Embodiment 2

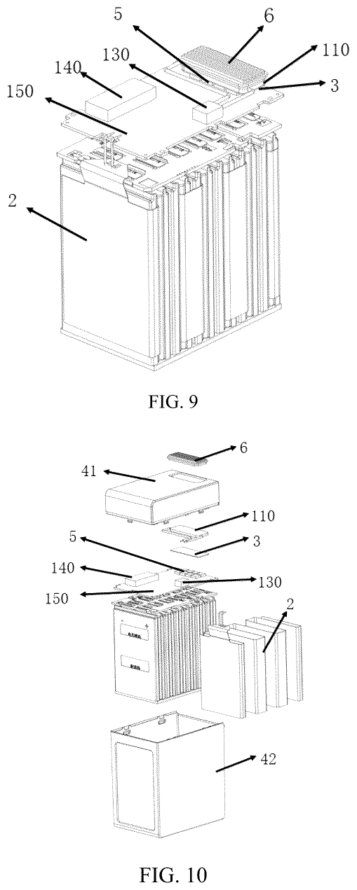

Referring to FIGS. 9 and 10, a battery cell heating system 10 provided in Embodiment 2 is another battery module. FIGS. 9 and 10 are schematic structural diagrams of a battery module according to Embodiment 2 of the present application. The battery module may include: a cell set 1, a heating element 5, a heat dissipating sheet 6, a thermoelectric conversion module 110, a heating film, and a housing 4; where
the thermoelectric conversion module 110 is provided between the heating element 5 and the heat dissipating sheet 6 and is in contact with the heating element 5 and the heat dissipating sheet 6 respectively;
a groove matching the heat dissipating sheet 6 is provided on the housing 4 and the heat dissipating sheet 6 is provided in the groove; and
the thermoelectric conversion module 110 is electrically connected to the heating film, and the heating film heats cells 13 through the thermoelectric conversion module 110.

In this embodiment, during the operation of the battery, the most severely heated part is a chip. Therefore, the heating element 5 is the chip, meanwhile, the heating element 5 is used as a heat source 100 and the heat dissipating sheet 6 is used as a cold source 120, and the heating film serves as a heating member 2 for heating the cells 13. The thermoelectric conversion module 110 is provided between the chip and the heat dissipating sheet 6. Since the position for the chip is uneven, a layer of aluminum sheet used as a heat conducting sheet 3 is further added between the chip and the thermoelectric conversion module 110 so as to ensure a smooth contact surface, so that the thermoelectric conversion module 110 can better receive heat from the chip (the heat source 100). If necessary, a thermal conductive silicone grease can be applied at gaps of the chip so as to further improve a heat conducting effect between the chip and the thermoelectric conversion module 110. The aluminum sheet is in direct contact with the thermoelectric conversion module 110, and the thermoelectric conversion module 110 is in direct contact with the heat dissipating sheet 6. The electric energy generated by the thermoelectric conversion module 110 is amplified by the amplifying module 130, then is stored in the energy storage module 140. When a battery or other system needs to be used in cold conditions, under the control of the control module 150, the electric energy stored in the energy storage module 140 is released to the heating film that plays a role in heating the cells 13 of the cell set 1. After the cells 13 are heated to an appropriate temperature, the battery can work normally in cold conditions. When the heating film performs heating, in order to make respective cells 13 heated more evenly, the heating film is designed as a thin sheet, and the heating thin sheet is folded for many times to form a folding structure as shown in the figures. The cells 13 are placed in the folding structure, so as to ensure that each cell 13 has a large surface in direct contact with the heating film. Because the outermost cell 13 has better heat dissipation conditions compared to the inner cells 13, both the front and back large surfaces of the outermost cell 13 are in direct contact with the heating film. The heating film is connected to the control module 150 through a wire, and forms a loop with the energy storage module 140 and the control module 150 during the heating process.

In an implementation, the heat dissipating sheet 6 is finned, heat dissipating sheet 6 is uniformly provided on one side of the thermoelectric conversion module 110, and the other side of the thermoelectric conversion module 110 is connected to the heating element 5.

In an implementation, a circuit board is further included, one end of the circuit board is in contact with the thermoelectric conversion module 110, and the heating element 5 is connected to the other end of the circuit board.

Specifically, the heat dissipating sheet 6 is designed to be exposed to air and the contact surface with the air is made into a finned design so as to enhance the convective heat dissipation between the heat dissipating sheet 6 and the air. Therefore, the temperature difference between the chip and the heat dissipating sheet 6 is larger, and more heat passes through the thermoelectric conversion module 110, so as to generate more electric energy. The heat dissipating sheet 6 is fixed to the housing 4 in a manner of hollowing out an area of the housing 4 where the heat dissipating sheet 6 is placed, placing the heat dissipating sheet 6 into the hollowed area of the battery upper housing 41 at where the heat dissipating sheet 6 is mounted, and directly contacting a flat surface of the heat dissipating sheet 6 with the thermoelectric conversion module 110.

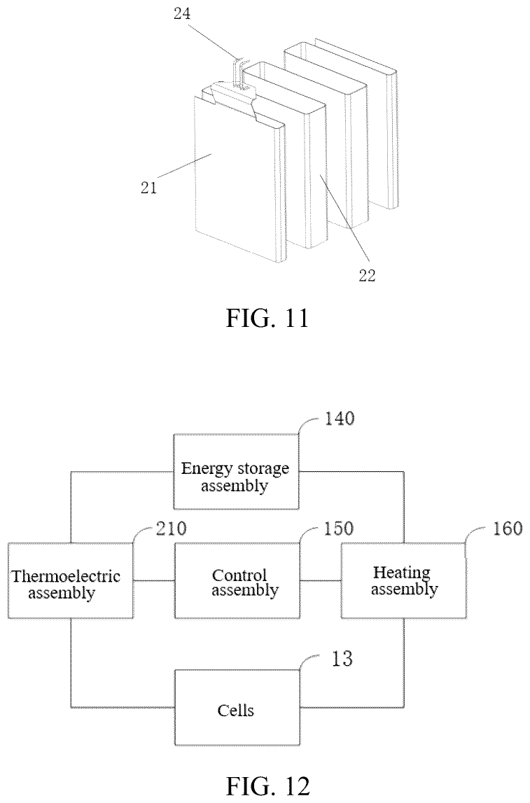

In another embodiment, FIG. 11 is a schematic structural diagram of the heating film in this embodiment. The cell set 1 includes a plurality of cells 13 arranged in parallel;
the heating film includes a plurality of heating portions 21 arranged in parallel along the arrangement direction of the cells 13, and first connection portions 22, each of which connects two adjacent heating portions 21; and
at least one surface of each of the cells 13 is in contact with the heater portion 21.

Each of the cells 13 includes two first side surfaces provided opposite to each other and two second side surfaces provided opposite to each other;
the first side surfaces have an area greater than that of the second side surfaces; and
at least one of the first side surfaces of each of the cells 13 is in contact with the heating portion 21.

Each cell 13 includes a first cell 13 located at a first side and a second cell 13 located at a second side opposite to the first side;
two first side surfaces of the first cell 13 are in contact with the heating portions 21 respectively, and/or
the two first side surfaces of the second cell 13 are in contact with the heating portions 21 respectively.

An angle is formed between each heating portion 21 and each first connecting portion 22, and the angle is an arc angle or a linear angle.

The angle is in a range of 0-90°

At least two cells 13 are accommodated between two adjacent heating portions 21.

In this embodiment, the heating film is a folding structure. The folding structure includes a plurality of heating portions 21 and a plurality of first connecting portions 22 provided between any two of the heating portions 21. The cells 13 are disposed in the first connecting portions 22, respectively. The heating module 160 further includes a connecting wire 24, where one end of the connecting wire 24 is connected to one end of the heating portions 21, the other end of the connecting wire 24 is connected to the control module 150, and the connecting wire 24 is configured to provide an operation voltage for the heating module 160. The cell 13 is in in a long body shape, and the first side surface of the cell 13 is a surface having a larger area, and the second side surface is a surface having a smaller area. By contacting the surface having the larger area with the heating portion 21, the cell 13 can be better heated. Two or more cells 13 are accommodated between adjacent heat conducting portions 31, and the specific number can be is adjusted according to actual situations. The angle between the heat conducting portion 31 and the second connecting portion 32 generally needs to be less than 90°, and when the angle is greater than 90°, the cell 13 cannot completely contact the heat conducting portion 31, thereby causing a problem of uneven heating.

Specifically, the heating film is designed as a thin sheet, the heating film is folded for many times to form a folding structure, and the plurality of cells 13 are placed in the folding structure, so as to ensure that each cell 13 has a large surface in direct contact with the folding structure, thereby achieving the effects of increasing the heating rate and reducing the temperature differences between respective cells 13 during heating.

The battery cell heating system 10 provided in Embodiment 2 of the present application is a battery module. The battery module includes: a cell set 1, a heating element 5, a heat dissipating sheet 6, a thermoelectric conversion module 110, a heating film and a housing 4. The thermoelectric conversion module 110 is provided between the heating element 5 and the heat dissipating sheet 6 and is in contact with the heating element 5 and the heat dissipating sheet 6 respectively. The housing 4 of the battery is provided with a groove matching the heat dissipating sheet 6 and the heat dissipating sheet 6 is provided in the groove. The thermoelectric conversion module 110 is electrically connected to the heating film, and the heating film heats the cells 13 through the thermoelectric conversion module 110. In the embodiment of the present application, waste heat generated during the operation of the chip is converted into electric energy and then the electric energy is stored in an energy storage device, and when the battery is started under cold conditions, the electric energy in the energy storage apparatus is converted into heat and the heat is provided for the cells 13, thereby achieving the effects of reducing the use cost of the battery under cold conditions and improving the battery life cycle.

Referring to FIG. 12, FIG. 12 is a schematic block diagram of a battery module according to the embodiment of the present application, including: a thermoelectric module 210, cells 13, a control module 150, a heating module 160, and an energy storage module 140. The heating module 160 is in contact with the cells 13. The energy storage module 140 is connected to the thermoelectric module 210 and the heating module 160 respectively. The control module 150 is electrically connected to the thermoelectric module 210 and the heating module 160 respectively. The thermoelectric module 210 includes a chip, a heat dissipating sheet 6 and a thermoelectric conversion module 110. The thermoelectric module 210 is configured to generate a first voltage according to a temperature difference between the chip and the heat dissipating sheet 6. The energy storage module 140 is configured to store the first voltage. The heating module 160 is configured to heat the cells 13 according to the first voltage. The control module 150 is configured to control the thermoelectric module 210 to charge an energy storage apparatus or control the heating module 160 to heat the cell 13.

In this embodiment, the thermoelectric module 210 utilizes the Seebeck effect thermoelectric conversion technology and provides the thermoelectric conversion module 110 between the chip and the heat dissipating sheet 6. The thermoelectric conversion module 110 includes multiple groups of thermoelectric conversion units. The thermoelectric conversion units can convert heat generated during the operation of battery into electric energy, which is subjected to voltage amplification and charging and discharging control process by the control circuit, then can be stored in a battery, a capacitor and other storage devices, thereby effectively solving the heating problem of the battery, reducing the temperature of critical components such as the cell 13, improving the working performance and service life of the battery, and enhancing the user experience.

Furthermore, the chip is a heat source 100, the heat dissipating sheet 6 is a cold source 120, the thermoelectric conversion module 110 is provided between the heat source 100 and the cold source 120, and the thermoelectric conversion module 110 is in contact with the heat source 100 and the cold source 120 respectively. The thermoelectric module 210 further includes an aluminum sheet. The aluminum sheet is provided between the chip and the thermoelectric conversion module 110, and the aluminum sheet is used for enhancing the heat conducting capability of the thermoelectric conversion module 110, that is, the aluminum sheet forms the heat conducting sheet 3.

In this embodiment, a drone battery is used as an example, the chip in the battery module has the highest heat generation. The heat dissipating sheet 6 of the cold source 120 is the component with the lowest temperature. The thermoelectric conversion module 110 is provided between the chip and the cold source 120. The thermoelectric conversion module 110 includes multiple groups of thermoelectric conversion units, and when heat passes through the thermoelectric conversion module 110, the thermoelectric conversion module 110 can generate electric energy. When the battery is in operation, a current passes through the chip, so that the chip generates heat, and the heat needs to pass through the thermoelectric conversion module 110 during a process of conducting or radiating the heat to the cold source 120. In order to obtain more electric energy through the thermoelectric conversion module 110 without changing the size thereof, it is necessary to increase the temperature difference between the two sides of the thermoelectric conversion module 110, i.e., between the chip and the cold source 120.

In this embodiment, the control module 150 is a circuit board, and the energy storage module 140 and the amplifying module 130 are provided on the control module 150.

Specifically, the control module 150 is configured to control the thermoelectric conversion module 110 to charge the energy storage module 140 or control the heating film to heat the cell 13. The control module 150 may be a preset circuit board storing control programs. For example, the heating module 160 may be a heating apparatus such as the heating film.

The cold source 120 in contact with the thermoelectric conversion module 110 is exposed to the air, the thermoelectric conversion module 110 is placed between the cold source 120 that is in contact with the outside and the heat source 100 that is located inside the battery, the temperature difference between the two ends of the thermoelectric conversion module 110 is increased, so that more heat can pass through the thermoelectric conversion module 110, thereby generating more electric energy. Meanwhile, because the cold source 120 is exposed to the air, the cold source 120 absorbs the heat from the inside of the battery, and the heat can be quickly dissipated to the outside, thereby enhancing the heat dissipation effect of the battery. Therefore, the heat dissipation capability of the battery is improved, and waste heat generated during the operating of the battery can also be recovered to a greater extent, thereby enhancing user experience.

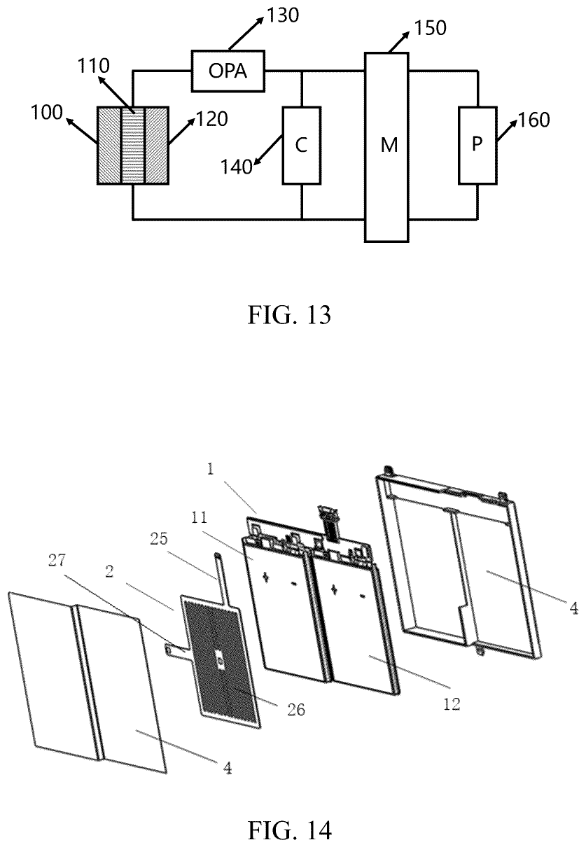

In another embodiment, referring to FIG. 13, FIG. 13 is a schematic structural diagram of a circuit in this embodiment, and further includes an amplifying module 130. The energy storage module 140 is provided between the thermoelectric module 210 and the heating module 160, and the energy storage module 140 is configured to store a first voltage. When the heating module 160 is in operation, the energy storage module 140 releases a second voltage generated by the first voltage and provides the second voltage to the heating module 160, and the heating module 160 heats the cells 13. The amplifying module 130 is provided between the thermoelectric module 210 and the energy storage module 140, and is connected to the thermoelectric module 210 and the energy storage module 140 respectively. The amplifying module 130 is used to amplify the first voltage and then transmit it to the energy storage module 140 so as to charge the energy storage module 140.

The component that generates the most heat in the battery is the chip on the circuit board, and the component with the lowest temperature is the cold source 120. The thermoelectric conversion module 110 is provided between the chip and the cold source 120, where the thermoelectric conversion module 110 includes multiple groups of thermoelectric conversion units, and when heat passes through the thermoelectric conversion module 110, the thermoelectric conversion module 110 can generate electric energy. When the battery in operation, a current passes through the chip, so that the chip generates heat, and the heat needs to pass through the thermoelectric conversion module 110 during a process of conducting or radiating the heat to the cold source 120. In order to obtain more electric energy through the thermoelectric conversion module 110 without changing the size thereof, it is necessary to increase the temperature difference between the two sides of the thermoelectric conversion module 110, i.e., between the chip and the cold source 120. The electric energy generated by the thermoelectric conversion module 110 is amplified by the amplifying module 130, and then is stored in the energy storage module 140, where the amplifying module 130 has a function of increasing the voltage. In this embodiment, an operational amplifier is taken as an example, and the potential difference generated by the thermoelectric conversion module 110 is amplified to be higher than the voltage value of the electric energy stored in the energy storage module 140. For the energy storage module 140, various devices having power storage capability may be used, such as capacitors, specially designed low-temperature batteries, etc., and a capacitor is taken as an example in this embodiment. The control module 150 can control the discharging process of the energy storage module 140, and can cause the electric energy stored in the energy storage module 140 to be released, adjusted and matched, and then supplied to the heating module 160 when the battery needs to be heated. Under cold conditions, when the battery or other systems need to be used, the electric energy is supplied to the heating module 160 to heat the battery to a normal operating temperature, thereby satisfying the user's use requirements.

In the solution of the present embodiment, waste heat during the operation of the device is converted into electric energy, and the electric energy is stored in an electric storage apparatus such as a battery or a capacitor, and is adjusted and controlled by the control circuit, and then is supplied to the heating apparatus inside the battery under cold conditions so as to make the heating apparatus provide heat to cells 13. Therefore, the battery can reach a good discharge temperature under cold conditions without an external power supply, thereby ensuring the normal discharging capability of the battery and providing a stable power supply for the operation of the device. In this process, there is a charging process in which the control module 150 controls the energy storage module 140 to control electric energy acquired by thermoelectric conversion to the energy storage module 140, and at the same time there is a discharging process in which the control circuit controls the energy storage module 140 to discharge the heating module 160, so that the heating module 160 heats the cell 13 to an appropriate temperature, and provides protection for the circuit.

The battery heating system 10 provided in the present application is a battery module, including a cell set 1, a heating element 5, a heat dissipating sheet 6, a thermoelectric conversion module 110, a heating film and a housing 4. The thermoelectric conversion module 110 is provided between the heating element 5 and the heat dissipating sheet 6, and is in contact with the heating element 5 and the heat dissipating sheet 6 respectively. A groove matching the heat dissipating sheet 6 is provided on the housing 4 of the battery, and the heat dissipating sheet 6 is provided in the groove. The thermoelectric conversion module 110 is electrically connected to the heating film, and the heating film heats the cell 13 through the thermoelectric conversion module 110. In the embodiment of the present application, waste heat generated during the operation of the chip is converted into electric energy and then the electric energy is stored in an energy storage apparatus. When the battery is started under cold conditions, the electric energy in the energy storage apparatus is converted into heat and the heat is provided to the cells 13, thereby achieving the effects of reducing the use cost of the battery under cold conditions and improving the battery life cycle.

### Embodiment 3

Batteries are considered to be widely used in electronic products such as smartphones and notebook computers. In electronic products represented by notebook computers, a battery including a plurality of cells 13 is generally used to provide electric energy for a notebook computer. However, the number of cells 13 used in existing electronic products may be unevenly distributed, resulting in a temperature difference between a plurality of cells 13. The long-term temperature difference may lead to a short battery cycle life, thereby causing abnormal weakening of battery capacity. It can be seen that there is a problem of poor battery use cycling due to a temperature difference of cells 13 in the existing technology.

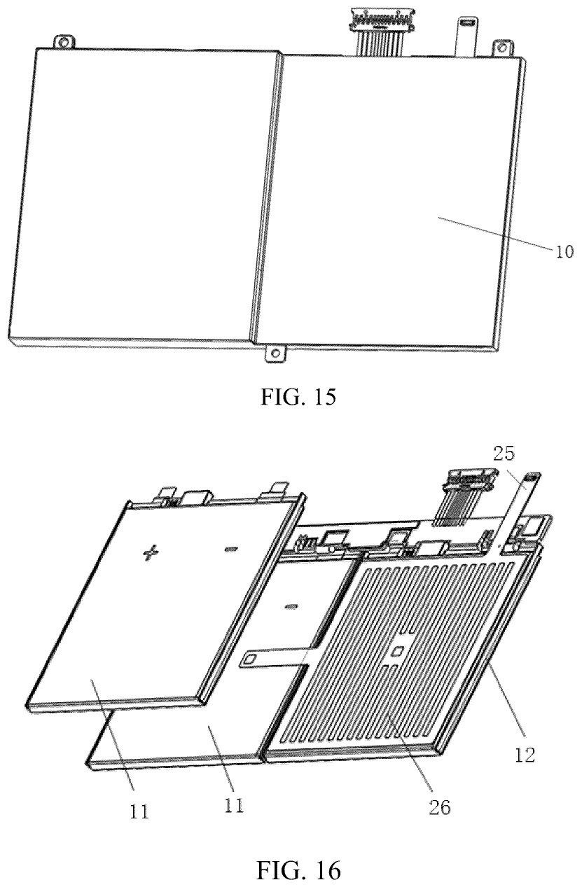

Therefore, the battery cell heating system 10 provided in Embodiment 3 is an electronic device, and the electronic device may include a battery module. As shown in FIGS. 14 to 17, the battery module includes a housing 4, a cell set 1 and a heating member 2. The cell set 1 includes a first cell unit 11 and a second cell unit 12. The heating member 2 includes a connecting area 25 and a heat conducting area 26, where the connecting area 25 is configured to be connected to the energy storage module 140, the heat conducting area 26 is attached to the second cell unit 12. The heating member 2 is configured to conduct heat energy to the heat conducting area 26 through the connecting area 25 when a temperature difference between the first cell unit 11 and the second cell unit 12 is greater than a preset value.

In this embodiment, the cell set 1 is covered by the housing 4 which protects the cell set 1. The heating member 2 is attached to the cell set 1 including the first cell unit 11 and the second cell unit 12. The heating member 2 includes the connecting area 25 and the heat conducting area 26. The connecting area 25 is configured to be connected to the energy storage module 140. The heat conducting area 26 is located at the second cell unit 12 and is attached to any cell 13 of the second cell unit 12. When the temperature difference between the first cell unit 11 and the second cell unit 12 is greater than the preset value by means of the measuring of a temperature measuring component, the heating member 2 conducts heat energy to the heat conducting area 26 through the connecting area 25, thereby reducing the temperature difference between the first cell unit 11 and the second cell unit 12. By means of the arrangement of the structure, the temperature difference between the first cell unit 11 and the second cell unit 12 can be kept within a preset value range, thereby improving the use cycle of the battery.

Where, the number of cells 13 in the first cell unit 11 along a thickness direction of the battery may be greater than the number of cells 13 in the second cell unit 12 in the thickness direction of the battery, that is, the number of cells 13 in the first cell unit 11 is inconsistent with the number of cells 13 in the second cell unit 12 in the thickness direction of the battery, so that the temperature difference is generated between the first cell 13 and the second cell 13. Therefore, there needs a temperature adjustment between the first cell unit 11 and the second cell unit 12.

It should be noted that, the cells 13 in the first cell unit 11 and the second cell unit 12 are disposed in such a way that the cells are stacked in a direction perpendicular to the plate surface direction of the housing 4, so that the thickness direction of the battery is perpendicular to the plate surface direction of the housing 4.

In addition, the heat conducting area 26 of the heating member 2 is located at the second cell unit 12 and is attached to any cell 13 of the second cell unit 12. When the number of cells 13 in the second cell unit 12 in the thickness direction of the battery is 1, the heat conducting area 26 is provided on a surface of a cell 13, facing the housing 4, of the second cell unit 12. When the number of cells 13 of the second cell unit 12 in the thickness direction of the battery is greater than 1, the heat conducting area 26 can be provided between a single cell 13 and a single cell 13 of the second cell unit 12, or the heat conducting area 26 can be provided on the surface of the cell 13, closest to the housing 4, of the second cell unit 12, which is not limited in the present application.

It should be understood that a temperature measuring component in the electronic device may be provided for the temperature measuring of the first cell unit 11 and the second cell unit 12. The temperature measuring component in the electronic device may be provided for the temperature measuring of the first cell unit 11 and the second cell unit 12. In addition, a component, which can measure the cell set 1, may also be provided on the heating member 2 for the temperature measuring of the first cell unit 11 and the second cell unit 12, which is not limited in the embodiments of the present application.

Of course, the connecting area 25 may be connected to any component to which the heating member 2 is able to provide output. For example, the connecting area 25 can be an output component connected to the interior of the electronic device, and the electronic device converts waste heat generated by the electronic device into heat energy required by the heating member 2. In addition, the connecting area 25 can also be connected to an external output component, and the external output component directly heats the heating member 2.

In addition, the material of the housing 4 may be a plastic material, and may be a hard plastic material in some embodiments, and may be a thermoplastic engineering plastic in other embodiments.

In addition, the heating member 2 includes the connecting area 25 and the heat conducting area 26. The connecting area 25 is configured to be connected to the energy storage module 140. The energy storage module 140 may be a built-in component capable of transmitting energy or storing energy in the electronic device. The heat conducting area 26 may include a heat conducting structure, and the heating member 2 conducts heat energy to the heat conducting area 26 through the connecting area 25, that is, the heat conducting structure in the heat conducting area 26 receives the heat energy, thereby providing heat to the second cell unit 12.

It should be understood that, an insulation covering structure on the external surface of the heating member 2 may be an integrated structure, and may also be a structure composed of multiple structures assembled together as a whole, which is not limited in the embodiment of the present application.

In an implementation, the heating member 2 further includes a measuring area 27. The measuring area 27 extends from the heat conducting area 26 to the first cell unit 11, and the measuring area 27 is attached to the first cell unit 11. The measuring area 27 is provided with a first temperature sensor, the heat conducting area 26 is also provided with a second temperature sensor, the first temperature sensor is configured to measure the temperature of the first cell unit 11, and the second temperature sensor is configured to measure the temperature of the second cell unit 12.

In this embodiment, the heating member 2 includes the connecting area 25, the heat conducting area 26 and the measuring area 27, and the measuring area 27 is a non-heat conducting area. The measuring area 27 extends from the heat conducting area 26 to the first cell unit 11, the first temperature sensor is provided in the measuring area 27, and the second temperature sensor is provided in the heat conducting area 26. By means of the arrangement of the first temperature sensor and the second temperature sensor, the temperatures of the first cell unit 11 and the second cell unit 12 may be acquired in real time, therefore, whether the temperatures of the first cell unit 11 and the second cell unit 12 are within a preset value can be determined, thereby reducing the battery damage caused by the excessively large temperature difference between the first cell unit 11 and the second cell unit 12.

Among them, the measuring area 27 can be a non-heat conducting area and is only configured for the measuring of the temperature of the cell 13.

It should be noted that the measuring area 27 extends from the heat conducting area 26 to the first cell unit 11. The measuring area 27 may be in an elongated shape, that is, the first temperature sensor is provided in the elongated measuring area 27. The position of the first cell unit 11, to which the measuring area 27 extends, may be a position close to the center of the first cell unit 11, thereby improving the accuracy of obtaining a temperature of the first cell unit 11.

In addition, the second temperature sensor is provided in the heat conducting area 26, where the position of the second sensor can be set in a position near the center of the heat conducting area 26 so as to improve the accuracy of obtaining the temperature of the second core unit 12. The second temperature sensor needs to be disposed at a certain distance from the heat conducting structure in the heat conducting area 26, and the distance between the second temperature sensor and the heat conducting structure can be controlled in a range of greater than or equal to 5 mm, so as to reduce the effect on the monitoring of the second temperature sensor due to the heat generated by the heat conducting structure.

It should be noted that the measuring area 27 can be an extension of the heat conducting area 26 to the first cell unit 11 in a same horizontal direction, that is, a connection between the heat conducting area 26 and the measuring area 27 is in an unbent state, or in other words, a length of the heat conducting area 26 in the thickness direction of the cells 13 of the second cell unit 12 is consistent with a length of the measuring area 27 in the thickness direction of the cells 13 in the first cell unit 11. By means of the arrangement of the structure, i.e. the obtaining of temperature values on the same thickness directions of the cells 13 can improve the temperature measurement accuracy for the first cell unit 11 and the second cell unit 12. On the other hand, the bending structure of the heating member 2 is reduced, thereby saving the use of the material of the heating member 2.

In an implementation, the measuring area 27 is provided between any two adjacent cells 13 in the first cell unit 11.

In this embodiment, the number of cells 13 included in the first cell unit 11 is greater than 1, and the measuring area 27 is provided between any two adjacent cells 13 in the first cell unit 11, that is, the first temperature sensor is located between any two adjacent cells 13 in the first cell unit 11. By means of the arrangement of the structure, the measurement accuracy of the first temperature sensor for the temperature of the first cell unit 11 can be improved, thereby improving the temperature difference control for the first cell unit 11 and the second cell unit 12.

It should be noted that, a position where the measuring area 27 is attached to the cell 13 in the first cell unit 11 may be provided according to a specific structure and size of the battery, which is not limited in the embodiments of the present application.

In an implementation, the number of the cells 13 of the second cell unit 12 in the thickness direction is greater than 1, and the heat conducting area 26 is provided between any two adjacent cells 13 of the second cell unit 12.

In this embodiment, when the number of cells 13 of the second cell unit 12 in the thickness direction is greater than 1, the heat conducting area 26 is provided between any two adjacent cells 13 of the second cell unit 12. By means of the arrangement of the structure, the overall heating effect of the heat conducting area 26 on the second cell unit 12 is improved.

On the other hand, a temperature measuring device for detecting the second cell unit 12 can also be provided in the heat conducting area 26, and by means of the arrangement of the structure, the temperature detection accuracy for the second battery cell unit 12 can be improved.

In an implementation, the heat conducting area 26 is provided with a plurality of heat conducting structures, and the plurality of heat conducting structures are provided at intervals.

In this embodiment, the heat conducting area 26 is provided with several heat conducting structures, and the several heat conducting structures are provided at intervals. By means of the arrangement of this structure, a heating fault caused by excessively close distances between the heat conducting structures is reduced, thereby improving the heating effect of the second cell unit 12.

The heat conducting structures may be copper sheets capable of conducting heat and generating heat, and may also be made of a material with high thermal conductivity, which is not limited in the embodiments of the present application.

It should be noted that, the heat conducting structures may have a thickness of 0.05 mm to 0.2 mm, and the specific thickness size may be provided according to the size of the heating member 2, which is not limited in the embodiments of the present application. In an implementation, several heat conducting structures are arranged in parallel in the heat conducting area 26.

In this embodiment, the heat conducting structures are arranged in parallel to each other in the heat conducting area 26. By means of the arrangement of this structure, the heating effect of the second cell unit 12 is improved, so that the temperature of the second cell unit 12 after the second cell unit 12 is heated and the temperature of the first cell unit 11 can be within a preset value, thereby improving the battery use cycle.

Where, the heat conducting structures may be made into an elongated shape, and may also be made into a shape suitable for the battery structure, which is not limited in the embodiments of the present application.

It should be noted that the heat conducting structures may be arranged in the heat conducting area 26 at intervals of a certain distance, and the distance may be determined according to the structure size of the battery, which is not limited in the embodiments of the present application.

In addition, the size of a single heat conducting structure may also be determined according to the heating demand and the size of the battery structure, which is not limited in the embodiments of the present application.

In an implementation, the distance between the several heat conducting structures is greater than or equal to 5 mm, and/or; the thickness of the several heat conducting structures is greater than or equal to 0.05 mm, and the thickness of the several heat conducting structures is less than or equal to 0.2 mm.

In this embodiment, the distance between the several heat conducting structures may be set to be greater than or equal to 5 mm, so as to reduce damage to the battery caused by close arrangement of the heat conducting structures. In addition, the thickness of the several heat conducting structures may be set to be greater than or equal to 0.05 mm and less than or equal to 0.2 mm. By means of the arrangement of this structure, the damage to the battery caused by inappropriate position arrangement of several heat conducting structures can be reduced. On the other hand, the heat conducting area 26 can also be uniformly heated.

In an implementation, the heating member 2 includes a first insulation layer, a second insulation layer, and the heating member 2, a connector, and a control circuit that are located between the first insulation layer and the second insulation layer. The heating member 2 is located in the heat conducting area 26, the connector is located in the connection area 25, and the heating member 2 is electrically connected to the connector through the control circuit.

Where, the connector is provided in the connection area 25.

In this embodiment, the heating member 2 includes a three-layer structure, including the first insulation layer, the second insulation layer, and the heating member 2, the connector, and the control circuit that are provided between the first insulation layer and the second insulation layer, where the connector is located in the connecting area 25, and the heating member 2 is electrically connected to the connector through the control circuit. By means of the arrangement of this structure, the heating member 2 mentioned above can be disassembled and modified more conveniently, and can be correspondingly modified along with the change of the battery structure. On the other hand, the arrangement of the three-layer structure can improve the safety performance of the battery, and reduce the possibility of electric leakage caused by direct contact between the heating member 2 and the battery.

In addition, the outside of the heating member 2 is wrapped by the insulation film mentioned above, so that the protection of the heating member 2 is improved, and at the same time, the influence of the external environment on the heating member 2 can also be reduced, thereby improving the heating effect of the second cell unit 12.

It should be noted that, the first insulation layer and the second insulation layer mentioned above may be made of an insulation material suitable for the battery, for example, a polyimide material, which is not limited in the embodiments of the present application.

Furthermore, the thickness of the first insulation layer and the second insulation layer may be provided within the range of 0.05 mm to 0.1 mm.

The battery cell heating system 10 provided in the embodiments of the present application is an electronic device including the battery described above, and the connecting area 25 of the heating member 2 of the battery is connected to the energy storage module 140 of the electronic device.

It should be noted that the electronic device may be a device such as a notebook computer or a smartphone. In an implementation, the electronic device further includes a thermoelectric conversion module 110, where the thermoelectric conversion module 110 is connected to a first end of the energy storage module 140, and the connector of the heating member 2 is connected to a second end of the energy storage module 140.

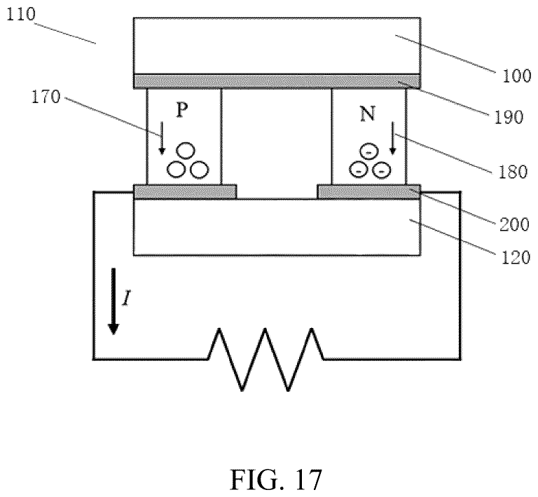

Please refer to FIG. 17, FIG. 17 shows the thermoelectric conversion module 110 in an electronic device, where the heat source 100 and the cold source 120 can be components for generating heat in the electronic device, For example, if the electronic device is a notebook computer, a central processing unit (CPU) in the notebook computer is used as the heat source 100 in the thermoelectric conversion power supply, while the metal housing 4 in the notebook computer can serve as the cold source 120 in the thermoelectric conversion module 110 because the temperature of the metal housing 4 and room temperature are consistent under normal working conditions.

In addition, the heat source 100 needs to be connected to a heat source connecting sheet 190, the cold source 120 needs to be connected to a cold source connecting sheet 200, and a first thermoelectric material 170 and a second thermoelectric material 180 are provided between the heat source connecting sheet 190 and the cold source connecting sheet 200.

It should be understood that the heat source 100 is closely attached to the heat source connecting sheet 190, and the larger the sectional area of the heat source connecting sheet 190 is, the higher the heat transfer efficiency is. Ends of the first thermoelectric material 170 and the second thermoelectric material 180 close to the cold source 120 are respectively connected to an external circuit, so that electric energy generated therein can be conducted to the outside for use, i.e. can be connected to the connector in the heating member 2. The connector then converts the electric energy into heat energy to supply heat to the heat conducting structures. By means of the arrangement of this structure, the cyclic use of heat in the electronic device is improved, thereby extending the endurance time of the battery.

In an implementation, the thermoelectric conversion module 110 includes: a first connection member and a second connection member, where two ends of the first connection member are respectively connected to the heat source 100 and the cold source 120 in the electronic device; two ends of the second connection member are respectively connected to the heat source 100 and the cold source 120 in the electronic device; and the ends of the first connection member and the second connection member close to the cold source 120 are connected to an external circuit.

Where, the heat source 100 may include a heat source body and a heat source connecting sheet 190, and the cold source 120 may include a cold source body and a cold source 120 connecting sheet. The heat source body and the cold source body may be components that generate heat in the above-mentioned electronic device. For example, a notebook computer is taken as a target electronic device for example, a central processing unit in the notebook computer may serve as the heat source body in the thermoelectric conversion module 110, and the metal housing 4 of the notebook computer may serve as the cold source body in the thermoelectric conversion module 110.

It should be noted that the heat source body may be connected to the heat source connecting sheet 190, and the cold source body may be connected to the cold source connecting sheet 200.

In addition, the first connecting member and the second connecting member may be made of a thermoelectric material.

In this embodiment, the ends of the first connection member and the second connection member close to the cold source 120 are respectively connected to the external circuit, so that electric energy generated therein can be conducted to the outside for use, i.e. can be connected to the connector, and the connector then converts the electric energy into heat energy to supply heat to the heat conducting structures. By means of the arrangement of this structure, the cyclic use of heat in the electronic device is improved, thereby extending the endurance time of the battery.

In an implementation, the thermoelectric conversion module 110 is connected to the heat source 100 and the cold source 120 through a thermal conductive adhesive respectively.

In this embodiment, the connection between the thermoelectric conversion module 110 and the heat source 100 and the connection between the thermoelectric conversion module 110 and the cold source 120 may be achieved by using the thermal conductive adhesive. By using the thermal conductive adhesive to achieve the connection, the heat dissipation effect during the operation process can be improved. Meanwhile, the cured thermal conductive adhesive may be an elastic body having advantages of impact resistance and vibration resistance.

In an implementation, the external circuit includes an amplifying module 130 and a control module 150, where the ends of the first connecting member and the second connecting member close to the cold source 120 are connected to a first end of the amplifying module 130, a second end of the amplifying module 130 is connected to a first end of the control module 150, and a second end of the control module 150 is connected to the energy storage module 140.

In this embodiment, by means of the arrangement of the amplifying module 130 and the control module 150, the thermoelectric conversion effect in the electronic device can be improved, thereby improving the ability of the battery to control the temperature difference in the cell set 1.

It should be noted that, in this specification, the terms “include”, “comprise”, or any other variation thereof are intended to encompass a non-exclusive inclusion, so that a process, a method, an item, or an apparatus that includes a series of elements not only includes those elements, but also includes other elements that are not explicitly listed, or further includes inherent elements of the process, the method, the item, or the apparatus. Without further limitations, an element limited by “including a . . . ” does not exclude the existence of other identical elements in the process, method, item, or device including the element. In addition, it should be noted that the scope of the methods and devices in the embodiments of the present application is not limited to performing functions based on the discussed order, and may also include performing functions in a substantially simultaneous manner or in a opposite order according to the functions involved. For example, the described methods may be executed in an order different from that described, and various steps may be added, omitted, or combined. In addition, features described with reference to certain examples may be combined in other examples.

The embodiments of the present application are described above with reference to the accompanying figures, but the present application is not limited to the above embodiments. The specific embodiments mentioned above are merely exemplary rather than limiting. Under the inspiration of the present application, those ordinary skilled in the art can make various modifications and replacements, all of which fall within the scope of protection of the present application, without departing from the purposes of the present application and the scope claimed in the claims.

It should be noted that the above are only preferred embodiments of the present application and technical principles applied thereto. It should be understood by those skilled in the art that the present application is not limited to the specific embodiments described herein, and various obvious changes, readjustments and substitutions can be made by those skilled in the art without departing from the scope of protection of the present application. Therefore, although the present application is described in detail through the above embodiments, the present application is not limited to the above embodiments, and can further include more other equivalent embodiments without departing from the concept of the present application, and the scope of the present application is determined by the scope of the appended claims.

What is claimed is:

1. A battery cell heating system, comprising: a cell set, a heating member, an energy storage assembly, a heat source, a cold source, and a thermoelectric conversion assembly;
the heating member is in contact with the cell set;
the energy storage assembly is electrically connected to the heating member so as to supply electric energy to the heating member to generate heat energy; and
the thermoelectric conversion assembly is in contact with the heat source and the cold source respectively, and thermoelectric conversion assembly is electrically connected to the energy storage assembly so as to store generated electric energy to the energy storage assembly.

2. The battery cell heating system according to claim 1, wherein the cold source is a heat dissipating sheet, and the battery cell heating system further comprises a heat conducting sheet, and the heat conducting sheet is in contact with the heat source, and
the thermoelectric conversion assembly is in contact with the heat conducting sheet and the heat dissipating sheet respectively.

3. The battery cell heating system according to claim 2, wherein the cell set comprises a plurality of cells arranged in parallel;
the heating sheet comprises a plurality of heating portions arranged in parallel in an arrangement direction of the cells, and first connecting portions, each of which connects two adjacent heating portions; and
at least one surface of each of the cells is in contact with each of the heating portions respectively;
wherein each of the cells comprises two first side surfaces provided opposite to each other and two second side surfaces provided opposite to each other;
the first side surfaces have an area greater than that of the second side surfaces; and
at least one of the first side surfaces of each of the cells is in contact with each of the heating portions respectively;
wherein the heat source is the cells, the heating member is a heating sheet, and the heat dissipating sheet is located on one side of the heat conducting sheet away from the cells; and
the cells are in contact with the heating sheet and the heat conducting sheet, respectively;

4. The battery cell heating system according to claim 3, wherein each of the first connecting portions is provided with a slot,
the heat conducting sheet comprises heat conducting portions, each of which is inserted to the slot, and the heat conducting sheet and the heating sheet form a folding structure; and
at least one cell is located between each of the heat conducting portions and each of the heating portions.

5. The battery cell heating system according to claim 4, wherein the heat conducting sheet comprises second connecting portions, each of which connects adjacent heat conducting portions; and
the second connecting portions are in contact with the thermoelectric conversion assembly.

6. The battery cell heating system according to claim 4, wherein
in the arrangement direction of the cells, the folding structure comprises the heat conducting portions, two of which are located on two opposite sides of the folding structure, respectively.

7. The battery cell heating system according to claim 4, wherein a length of each of the heating portions is greater than a length of each of the heat conducting portions, and/or
in a height direction of the battery cell heating system, a height of the thermoelectric conversion assembly is higher than that of the heat conducting sheet, and/or
each of the cells comprises a shell and a cell body, wherein the shell comprises an encapsulation portion for encapsulating the cell body and a sealing edge located at one side of the encapsulation portion, and the sealing edge is bent towards to a direction close to the cell body, and/or
each of the cells comprises a shell and a cell body, wherein the shell comprises an encapsulation portion for encapsulating the cell body, and adjacent cells have encapsulation portions disposed opposite to each other, and/or
the battery cell heating system further comprises buffer members located between the cells and the heating portions respectively, and/or, located between the cells and the heat conducting portions, respectively.

8. The battery cell heating system according to claim 5, wherein each of the cells comprises a first cell located at a first side and a second cell located at a second side opposite to the first side;
two first side surfaces of the first cell are in contact with each heat conducting portion and each heating portion respectively, and/or
the two second side surfaces of the second cell are in contact with each first connecting portion and each second connecting portion respectively.

9. The battery cell heating system according to claim 5, wherein an angle is formed between each heat conducting portion and each second connecting portion, and the angle is an arc angle or a linear angle.

10. The battery cell heating system according to claim 3, wherein the heat source is a heating element, the heating element is a heating film, and the battery cell heating system further comprises a housing, a groove matching the heat dissipating sheet is provided on the housing, and the heat dissipating sheet is provided in the groove; and
the thermoelectric conversion assembly is electrically connected to the heating sheet, and the heating sheet heats the cells through the thermoelectric conversion assembly;
wherein the heat dissipating sheet is finned, and the heat dissipating sheet is evenly provided on one surface of the thermoelectric conversion assembly, and the other surface of the thermoelectric conversion assembly is connected to the heating element.

11. The battery cell heating system according to claim 10, wherein the battery cell heating system further comprises a circuit board, wherein one end of the circuit board is in contact with the thermoelectric conversion assembly, and the heating element is connected to the other end of the circuit board.

12. The battery cell heating system according to claim 10, wherein each of the cells comprises a first cell located at a first side and a second cell located at a second side opposite to the first side;
two first side surfaces of the first cell are in contact with the heat conducting portions respectively, and/or
two first side surfaces of the second cell are in contact with the heat conducting portions respectively.

13. The battery cell heating system according to claim 3, wherein an angle is formed between each of the heating portions and each of the first connecting portions, and the angle is an arc angle or a linear angle;
wherein the angle is in a range of is 0-90°.

14. The battery cell heating system according to claim 3, wherein at least two cells are accommodated between two adjacent heating portions.

15. The battery cell heating system according to claim 1, wherein the cell set comprises a first cell unit and a second cell unit; and
the heating member comprises a connecting area and a heat conducting area, where the connecting area is configured to be connected with the energy storage assembly, the heat conducting area is attached to the second cell unit, and the heating member is configured to conduct heat energy to the heat conducting area through the connecting area when a temperature difference between the first cell unit and the second cell unit is greater than a preset value;
wherein the heating member further comprises a measuring area, and the measuring area extends from the heat conducting area to the first cell unit, and the measuring area is attached to the first cell unit; and
the measuring area is provided with a first temperature sensor, the heat conducting area is further provided with a second temperature sensor, wherein the first temperature sensor is configured to measure the temperature of the first cell unit, and the second temperature sensor is used for measure the temperature of the second cell unit;
wherein the number of the cells in the first cell unit along a thickness direction of the first cell unit is larger than 1, and the measuring area is provided between any two adjacent cells in the first cell unit;

16. The battery cell heating system (10) according to claim 15, wherein the heat conducting area is provided with a plurality of heat conducting structures, and the plurality of heat conducting structures are arranged at intervals;
wherein the plurality of heat conducting structures are arranged parallel to each other in the heat conducting area;
wherein distances between the plurality of heat conducting structures are greater than or equal to 5 mm, and/or
the plurality of heat conducting structures have a thickness of greater than or equal to 0.05 mm, and the plurality of heat conducting structures have a thickness of less than or equal to 0.2 mm.

17. The battery cell heating system according to claim 15, wherein the heating member comprises a first insulation layer, a second insulation layer, wherein the first insulation layer and the second insulation layer are located on opposite sides of the heating member respectively, wherein the heating member is located in the heat conducting area, and the heating member further comprises a connector located in the connecting area, and the heating member is electrically connected to the connector through a control circuit.

18. The battery cell heating system according to claim 2, further comprising a control assembly, wherein the control assembly is connected to the energy storage assembly, and the control assembly is configured to control the thermoelectric conversion assembly to charge the energy storage assembly or control the heating sheet to heat the cells;
wherein the battery cell heating system further comprising an amplifying assembly, wherein the amplifying assembly is provided between the thermoelectric conversion assembly and the energy storage assembly, and is respectively connected to the thermoelectric conversion assembly and the energy storage assembly, and the amplifying assembly is configured to amplify a voltage generated by the thermoelectric conversion assembly and transmit it to the energy storage assembly so as to charge the energy storage assembly;

19. The battery cell heating system according to claim 18, wherein the thermoelectric conversion assembly is connected to a first end of the energy storage assembly and the connector of the heating member is connected to a second end of the energy storage assembly;
wherein the thermoelectric conversion assembly comprises a first connecting member and a second connecting member, wherein two ends of the first connecting member are respectively connected to the heat source and the cold source;
two ends of the second connecting member are respectively connected to the heat source and the cold source; and
the end of the first connecting member and the end of the second connecting member, which are close to the cold source, are connected to the amplifying assembly and the control assembly;
wherein the thermoelectric conversion assembly is respectively connected to the heat source and the cold source by a thermal conductive adhesive.

20. The battery cell heating system according to claim 19, wherein the end of the first connecting member and the end of the second connecting member, which are close to the cold source, are connected to a first end of the amplifying assembly, a second end of the amplifying assembly is connected to a first end of the control assembly, and a second end of the control assembly is connected to the energy storage assembly.
